(19) United States
(12) Patent Application Publication
(10) Pub. No.: US 2014/0284649 A1
(43) Pub. Date: Sep. 25, 2014

(54) OPTOELECTRONIC COMPONENT AND PHOSPHORS

(71) Applicant: OSRAM Opto Semiconductors GmbH, Regensburg (DE)

(72) Inventors: Alexander Baumgartner, Donaustauf (DE); Frank Jermann, Konigsbrunn (DE); Stefan Lange, Augsburg (DE); Tim Fiedler, Munchen (DE)

(21) Appl. No.: 14/349,751

(22) PCT Filed: Sep. 26, 2012
(86) PCT No.: PCT/EP2012/069003

§ 371 Date: Apr. 4, 2014

(30) Foreign Application Priority Data
Oct. 12, 2011 (DE) 10 2011 115 879.4

(51) Int. Cl. H01L 33/50; C09K 11/77

(52) U.S. Cl. CPC H01L 33/504; C09K 11/7774; C09K 11/7728
USPC 257/98; 423/263

(57) ABSTRACT

An optoelectronic component includes a layer sequence having an active region that emits primary electromagnetic radiation, wherein the primary electromagnetic radiation has a wavelength of 430 nm to 470 nm, a conversion material arranged in a beam path of the primary electromagnetic radiation and at least partly converts the primary electromagnetic radiation into a secondary electromagnetic radiation, wherein the conversion material includes a first phosphor having general composition A₃B₅O₁₂, wherein A is a combination of Lu and Ce, and wherein B is a combination of Al and Ga.

### TECHNICAL FIELD

This disclosure relates to an optoelectronic component and phosphors.

### BACKGROUND

Radiation-emitting components such as light-emitting diodes (LED), for example, often contain converter materials to convert the radiation emitted by a radiation source into a radiation having altered, for example, longer wavelength. In this case, the efficiency of the converter material is generally dependent on the temperature and/or the current intensity and the operating current, respectively. Intensified losses of brightness and ageing phenomena of the component can also be the consequence of high temperatures during the operation of the component.

It could therefore be helpful to provide an optoelectronic component and phosphors which have an improved stability.

### SUMMARY

We provide an optoelectronic component including a layer sequence having an active region that emits primary electromagnetic radiation, wherein the primary electromagnetic radiation has a wavelength of 430 nm to 470 nm, a conversion material arranged in a beam path of the primary electromagnetic radiation and at least partly converts the primary electromagnetic radiation into a secondary electromagnetic radiation, wherein the conversion material comprises a first phosphor having general composition A₃B₅O₁₂, wherein A is a combination of Lu and Ce, Lu can be present in the first phosphor in a proportion of greater than or equal to 90 mol %, and wherein B is a combination of Al and Ga, a proportion of Ga can be 10 mol % to 40 mol %, and the conversion material comprises a second phosphor, and the second phosphor is selected from a group of the following second phosphors and combinations thereof: second phosphor from a M⁴-Al—Si—N system comprising a cation M⁴, wherein M⁴ comprises Ca or a combination of Ca with at least one further element from the group consisting of Ba, Sr, Mg, Zn and Cd, wherein the second phosphor is activated with Eu that partly replaces M4, wherein the second phosphor forms a phase that can be assigned to a system M⁴₃N₂—AlN—Si₃N₄, wherein an atomic ratio of constituents M⁴:Al≧0.375 and an atomic ratio Si/Al≧1.4, second phosphor from a M⁵-Al—Si—N system comprising a cation M⁵, wherein M⁵ comprises Ca or Ba or Sr, wherein M⁵ can additionally be combined with at least one further element selected from the group consisting of Mg, Zn and Cd, the second phosphor is activated with Eu that partly replaces M⁵, the second phosphor additionally contains LiF, and a proportion of LiF is at least 1 mol %, relative to M⁵, second phosphor M¹AlSiN₃.Si₂N₂O, second phosphor M³AlSiN₃, and second phosphor M₂Si₅N₈, wherein M is a combination of Ca, Sr, Ba and Eu, M¹ is selected from the group consisting of Sr, Ca, Mg, Li, Eu and combinations thereof, and M³ is selected from the group consisting of Sr, Ca, Mg, Li, Eu and combinations thereof.

We also provide a phosphor having a general composition A₃B₅O₁₂, wherein A is selected from the group consisting of Y, Lu, Gd, Ce and combinations thereof, and wherein B comprises a combination of Al and Ga.

We further provide a phosphor having a general composition M₂Si₅N₈, wherein M includes a combination of Ca, Sr, Ba and Eu.

### BRIEF DESCRIPTION OF THE DRAWINGS

FIG. 1 shows the schematic side view of an optoelectronic component.

FIG. 2 shows the temperature dependence of the relative brightness I of a second phosphor in accordance with one example compared to comparative examples.

FIG. 3 shows the temperature dependence of the relative brightness I of a second phosphor in accordance with a further example compared to comparative examples.

FIG. 4 shows the temperature dependence of the relative brightness I of a first phosphor in accordance with one example compared to comparative examples.

FIG. 5 shows the time dependence of the conversion efficiency of different examples of second phosphors and of a comparative example.

FIG. 6 shows the time dependence of the conversion efficiency of further examples of second phosphors and of a comparative example.

FIG. 7 shows the conversion ratio of examples of second phosphors and of a comparative example as a function of the Ca content.

FIG. 8 shows the relative quantum efficiency of a second phosphor in accordance with one example and a comparative example.

FIG. 9 shows the difference in the correlated color temperature of phosphor mixtures,

FIG. 10 shows the difference in the color rendering index of phosphor mixtures.

FIG. 11 shows the difference in the color rendering index of phosphor mixtures.

FIG. 12 shows the temperature dependence of the change in the color temperature of phosphor mixtures.

FIG. 13 shows the temperature dependence of the color rendering index of phosphor mixtures.

FIG. 14 shows the temperature dependence of the color rendering index of phosphor mixtures.

FIG. 15 shows the emission wavelength dependence of the intensity I of two examples of second phosphor.

FIG. 16 shows phosphor spectra at different excitation wavelengths of a first phosphor in accordance with one example.

FIG. 17 shows phosphor spectra at different excitation wavelengths of a comparative example.

FIG. 18 shows phosphor spectra at different excitation wavelengths of a comparative example.

FIG. 19 shows a converter loss of a second phosphor in accordance with one example and a comparative example.

### DETAILED DESCRIPTION

Our optoelectronic components may comprise a layer sequence having an active region that emits primary electromagnetic radiation, and a conversion material arranged in the beam path of the primary electromagnetic radiation and at least partly converts the primary electromagnetic radiation into a secondary electromagnetic radiation.

The conversion material comprises a first phosphor having the general composition A₃B₅O₁₂, wherein A is selected from a group comprising Y, Lu, Gd and Ce and combinations thereof, and wherein B comprises a combination of Al and Ga. The conversion material furthermore comprises a second phosphor, which is selected from a group of the following second phosphors and combinations thereof:
phosphor from the M⁴-Al—Si—N system comprising a cation M⁴, wherein M⁴ comprises Ca or a combination of Ca with at least one further element from the group Ba, Sr, Mg, Zn, Cd wherein this second phosphor is activated with Eu that partly replaces M⁴, wherein the second phosphor forms a phase that can be assigned to the system M⁴₃N₂—AlN—Si₃N₄, wherein the atomic ratio of the constituents M⁴:Al≧0.375 and the atomic ratio Si/Al≧1.4,
phosphor from the M⁵-Al—Si—N system comprising a cation M⁵, wherein M⁵ comprises Ca or Ba or Sr, wherein M⁵ can additionally be combined with at least one further element from the group Mg, Zn, Cd, wherein the second phosphor is activated with Eu that partly replaces M⁵, wherein the second phosphor additionally contains LiF, wherein the proportion of LiF is at least 1 mol %, relative to M⁵,
phosphor M¹AlSiN₃.Si₂N₂O,
phosphor M³AlSiN₃, and
phosphor M₂Si₅N₈, wherein M is a combination of Ca, Sr, Ba and Eu, M¹ is selected from a group comprising Sr, Ca, Mg, Li, Eu and combinations thereof, and M³ is selected from a group comprising Sr, Ca, Mg, Li, Eu and combinations thereof.

In this case, the first phosphor and/or the second phosphor need not necessarily have mathematically exact compositions according to the above formulae. Rather, they can comprise, for example, one or more additional dopants and additional constituents. For the sake of simplicity, however, the above formulae only include the essential constituents.

In particular, the second phosphor may be M¹AlSiN₃.Si₂N₂O and/or M³AlSiN₃ and/or M₂Si₅N₈.

It should be pointed out at this juncture that the term “component” is taken to mean not only finished components such as light-emitting diodes (LEDs) or laser diodes, for example, but also substrates and/or semiconductor layers such that, for example, a composite of a copper layer and a semiconductor layer can already constitute a component and can form part of a superordinate second component in which, for example, electrical connections are additionally present. The optoelectronic component can be, for example, a thin-film semiconductor chip, in particular a thin-film light-emitting diode chip.

In this context, “layer sequence” should be understood to mean a layer sequence comprising more than one layer, for example, a sequence of a p-doped and an n-doped semiconductor layer, wherein the layers are arranged one above another.

In this context, a “combinations of Al and Ga” with regard to the component B means that the component B of the first phosphor contains Al and Ga, wherein the sum of the proportions of Al and Ga is 100% if B contains no further elements, or less than 100% if besides Al and Ga even further elements are used for B.

For the component A of a first phosphor it is likewise possible to use one or at least two elements selected from the group comprising Y, Lu, Gd and Ce, wherein the sum of the proportions thereof amounts to 100%.

Color indications with regard to emissive phosphors designate the respective spectral range of the electromagnetic radiation.

Electromagnetic radiation, in particular electromagnetic radiation having one or more wavelengths or wavelength ranges from an ultraviolet to infrared spectral range, is also designated as light. Light can be visible light, in particular, and comprise wavelengths or wavelength ranges from a visible spectral range of between approximately 350 nm and approximately 800 nm. Visible light can be characterizable, for example, by its color location having cx and cy color location coordinates in accordance with the CIE-1931 color space diagram or the known CIE standard chromaticity diagram.

White light or light having a white luminous or color impression can denote light having a color location which corresponds to the color location of a Planckian black-body radiator or deviates from the color location of a Planckian black-body radiator by less than 0.07 and preferably by less than 0.05, for example, 0.03 in cx and/or cy color location coordinates. Furthermore, a luminous impression designated as a white luminous impression can be brought about by light having a color rendering index (CRI)—known to a person skilled in the art—of greater than or equal to 60, preferably of greater than or equal to 80 and particularly preferably of greater than or equal to 90.

We surprisingly discovered that during operation of an optoelectronic component, increased stability of the optoelectronic component at different ambient temperatures and operating currents arises as a result of a combination of the wavelength or the wavelength range of the primary electromagnetic radiation with the first and second phosphors. Furthermore, an increased efficiency of the conversion of the primary electromagnetic radiation into a secondary electromagnetic radiation, a higher brightness, a high color rendering index (CRI, R9, Ra8) and a better color impression of the light emitted by the component arise in comparison with conventional optoelectronic components.

The layer sequence can be a semiconductor layer sequence, wherein the semiconductor materials occurring in the semiconductor layer sequence are not restricted, provided that they can have electroluminescence at least in part. By way of example, use is made of compounds composed of elements which can be selected from indium, gallium, aluminium, nitrogen, phosphorus, arsenic, oxygen, silicon, carbon and combinations thereof. However, it is also possible to use other elements and additives. The layer sequence having an active region can be based on nitride compound semiconductor materials, for example. “Based on nitride compound semiconductor material” means that the semiconductor layer sequence or at least one part thereof comprises or consists of a nitride compound semiconductor material, preferably AlₙGaₘIn₁₋ₙ₋ₘN, wherein 0≦n≦1, 0≦m≦1 and n+m≦1. In this case, this material need not necessarily have a mathematically exact composition according to the above formula. Rather, it can comprise, for example, one or more dopants and additional constituents. For the sake of simplicity, however, the above formula includes only the essential constituents of the crystal lattice (Al, Ga, In, N), even if these can be replaced and/or supplemented in part by small amounts of further substances.

The semiconductor layer sequence can comprise as active region, for example, a conventional pn junction, a double heterostructure, a single quantum well structure (SQW structure) or a multiple quantum well structure (MQW structure). Besides the active region, the semiconductor layer sequence can comprise further functional layers and functional regions, for instance p- or n-doped charge carrier transport layers, that is to say electron or hole transport layers, p- or n-doped confinement or cladding layers, buffer layers and/or electrodes and combinations thereof. Such structures concerning the active region or the further functional layers and regions are known to the person skilled in the art in particular with regard to construction, function and structure and therefore will not explained in any greater detail at this juncture.

Alternatively, it is possible to select an organic light-emitting diode (OLED) as optoelectronic component, wherein, for example, the primary electromagnetic radiation emitted by the OLED is converted into a secondary electromagnetic radiation by a conversion material situated in the beam path of the primary electromagnetic radiation.

The second phosphor, for example, of the M₂Si₅N₈ type, exhibits a distinctly higher stability at high temperatures, such as 85° C. to 120° C., for example, and/or varying ambient temperatures and current intensities or currents. This higher stability and, in addition, an optimized position of the emission of the second phosphor, for example, of the M₂Si₅N₈ type, exhibits a distinctly stabler color rendering index (CRI and color rendering index with 8 reference colors, Ra8), a higher color rendering index for saturated red (R9), which remains at CRI 80 under all conditions above 0. Furthermore, the second phosphor, for example, of the M₂Si₅N₈ type, can be used without further stabilization measures in an optoelectronic component and is moisture-stable and thermally stable.

Furthermore, the color location of the second phosphor of the M₂Si₅N₈ type, by varying the ratio of the cations of the component M, Ca²⁺, Sr²⁺, Ba²⁺ and Eu²⁺, can be adapted to the eye sensitivity of an external observer and simultaneously to the emission of the primary electromagnetic radiation and the secondary electromagnetic radiation of the first phosphor (first secondary electromagnetic radiation hereinafter) such that a thermally stabler and current-stabler behavior of the total emission, that is to say the electromagnetic radiation of the component perceived by an external observer, is achieved and at the same time a sufficiently high color rendering index is obtained. A distinct stabilization of the color location of the component can furthermore be observed.

The secondary electromagnetic radiation of the second phosphor of the M₂Si₅N₈ type (second secondary electromagnetic radiation hereinafter) can be shifted toward higher wavelengths by reducing the average ion size of the cations Ca²⁺, Sr²⁺, Ba²⁺ or by increasing the proportion of Eu in the second phosphor of the M₂Si₅N₈ type.

We surprisingly discovered that partial substitutions of Sr by Ca in a phosphor of the (Sr,Ba,Eu)₂Si₅N₈ type leads to a significantly improved long-term stability and at the same time to a long-wave shift in the emission, without deep-red components from the spectral range of the second secondary radiation being excessively greatly pronounced. The temperature quenching behavior of the luminescence of the second phosphor of the M₂Si₅N₈ type in which M is a combination of Ca, Sr, Ba and Eu is significantly better compared to a phosphor of the (Sr,Ba,Eu)₂Si₅N₈ type, even though the partial substitution of Sr by Ca proceeding from a phosphor of the (Sr,Eu)₂Si₅N₈ type leads to an impaired temperature quenching behavior. A variation of the ratio of the cations Ca²⁺, Sr²⁺, Ba²⁺ and Eu²⁺ in component M of the second phosphor of the M₂Si₅N₈ type therefore leads to a thermally stabler optoelectronic component at varying ambient temperatures and/or operating currents, wherein, for example, high brightness values, a more stable color location, a more stable color temperature and a stable and high color rendering (Ra8, CRI, R9) are achieved during the operation of the optoelectronic component.

The second phosphor of the conversion material may be M₂Si₅N₈, wherein Ca is present in the second phosphor in a proportion of 2.5 mol % to 25 mol %, preferably 5 to 15 mol %.

Furthermore, the second phosphor can be M₂Si₅N₈ and contain Ba in a proportion that is greater than or equal to 40 mol %, for example, 40 mol % to 70 mol %, preferably greater than or equal to 50 mol %.

The second phosphor may be M₂Si₅N₈ and may contain Eu in a proportion of 0.5 mol % to 10 mol %, preferably 2 mol % to 6 mol %, particularly preferably 4 mol %. In this case, Eu can serve for activation and/or doping of the second phosphor.

The second phosphor may have the composition (Sr_{0.36}Ba_{0.5}Ca_{0.1}Eu_{0.04})₂Si₅N₈. As a result of the combination of Sr, Ba, Ca and Eu, a high thermal stability, a long-term stability of the component, a stability of the color location and a stability of the color rendering index (Ra8, CRI, R9) are achieved in the second phosphor having the composition (Sr_{0.36}Ba_{0.5}Ca_{0.1}Eu_{0.04})₂Si₅N₈.

Alternatively or additionally, it is possible to use a second phosphor of the M¹AlSiN₃.Si₂N₂O type, in particular (Sr_{1-x-y}CaₓEu_{y})AlSiN₃.Si₂N₂O where 0≦x≦1 and 0.003≦y≦0.007, or M³AlSiN₃, in particular (Sr_{1-a-b}CaₐEu_{b})AlSiN₃ where 0≦a≦1 and 0.003≦b≦0.007, in the conversion material, wherein the two second phosphors have an emission comparable to that of the second phosphor of the M₂Si₅N₈ type.

Alternatively or additionally, it is possible to use a second phosphor from the M⁴-Al—Si—N system comprising a cation M⁴ in the conversion material, wherein M⁴ comprises Ca or a combination of Ca with at least one further element from the group Ba, Sr, Mg, Zn, Cd, wherein this second phosphor is activated with Eu that partly replaces M⁴, wherein the second phosphor forms a phase that can be assigned to the system M⁴₃N₂—AlN—Si₃N₄, wherein the atomic ratio of the constituents M⁴:Al≧0.375 and the atomic ratio Si/Al≧1.4.

The second phosphor from the M⁴-Al—Si—N system may have the stoichiometry M⁴₅Al₄Si₈N₁₈:Eu. In particular, M⁴ may be Ca. The stoichiometry results from the composition of the starting materials and can therefore vary within certain limits in the compound.

The second phosphor from the M⁴-Al—Si—N system has outstanding thermal stability and a high stability of the centroid wavelength of the emission at changing temperatures.

The second phosphor from the M⁴-Al—Si—N system may have a dominant wavelength of 585 to 620 nm.

The second phosphor from the M⁴-Al—Si—N system may have the following composition: Ca_{5-δ}Al_{4-2δ}Si_{8+2δ}N₁₈:Eu where |δ|≦0.5.

In this case, the activator Eu respectively replaces the metal ion M⁴ in part, preferably at 0.5 to 5 mol %, particularly preferably at 1 to 3 mol %. The parameter 6 should in this case be |δ|≦0.5, preferably −0.5≦δ≦0.35. That is to say that the proportion of Si in the second phosphor is always at least 40% greater than the proportion of Al (Si/Al>1.4) and the Ca/(Al+Si) ratio is always greater than 0.375.

The second phosphor from the M⁴-Al—Si—N system may have a stoichiometry M⁴_{5-δ}Al_{4-2δ+y}Si_{8+2δ-y}N_{18-y}O_{y}:Eu where |δ|≦0.5 and 0≦y≦2. Consequently, it is possible to exchange SiN for AlO.

M⁴ in the second phosphor from the M⁴-Al—Si—N system may be identical to Ca or Ca_{1-z}(Mg,Sr)_{z} where z≦0.15.

The subject matter of DE 10 2006 036 577 is incorporated herein by reference, particularly the synthesis and/or properties of the phosphor.

Alternatively or additionally, it is possible to use a second phosphor from the M⁵-Al—Si—N system comprising a cation M⁵ in the conversion material, wherein M⁵ comprises Ca or Ba or Sr, wherein M⁵ can additionally be combined with at least one further element from the group Mg, Zn, Cd, wherein the second phosphor is activated with Eu but partly replaces M⁵, wherein the second phosphor additionally contains LiF, wherein the proportion of the LiF is at least 1 mol %, relative to M⁵.

The second phosphor from the M⁵-Al—Si—N system may have the nominal composition in the sense of batch stoichiometry Ca_{0.88}Eu_{0.02}Li_{0.1}AlSi(N_{0.967}F_{0.033})₃. The latter exhibits an emission maximum at approximately 655 nm.

The proportion of LiF in the second phosphor of the Ca_{0.98}Eu_{0.02}AlSiN type can be 0.1 mol-%, 0.15 mol-%, 0.05 mol-% or 0.2 mol-%. The relative brightness at high temperatures can be improved by the choice of the proportion of LiF in the second phosphor. A higher proportion of the LiF in the second phosphor increases the thermal stability.

The second phosphor from the M⁵-Al—Si—N system may have a dominant wavelength of greater than 610 nm.

M⁵ of the second phosphor from the M⁵-Al—Si—N system may be Ca alone or predominantly, to the extent of more than 50 mol %, and/or the proportion of LiF in the second phosphor from the M⁵-Al—Si—N system is at least 1 mol % and a maximum of 15 mol %, relative to M⁵.

In particular, Ca can be present to the extent of more than 70 mol % as M⁵ of the second phosphor.

The subject matter of EP 2 134 810 is incorporated herein by reference, particularly the synthesis and/or properties of the phosphor.

The first and second phosphors can be shaped as particles. By way of example, in this case the second phosphors of the M¹AlSiN₃.Si₂N₂O or M³AlSiN₃ type can additionally have a surface coating, for example with SiO₂ and/or Al₂O₃, whereby their moisture stability is improved.

The component A of the first phosphor having the general composition A₃B₅O₁₂ can comprise an activator and/or dopant. A composition of the first phosphor optimally adapted to the wavelength of the primary electromagnetic radiation can be achieved by varying the ratios of (Y, Lu, Gd, Ce) to (Al, Ga).

The first phosphor having the general composition A₃B₅O₁₂ may comprise Ce as component A. In this case, Ce can be present in the first phosphor in a proportion of 0.5 mol-% to 5-mol %, preferably 2 mol % to 3 mol %, particularly preferably 2.5 mol %. Ce can serve as activator and/or dopant in the first phosphor. By virtue of the high concentration of the Ce as activator in the first phosphor and a good correspondence of the absorption maximum of the first phosphor to the primary electromagnetic radiation, this results in a higher conversion efficiency of the first phosphor in comparison with conventional phosphors such as yellow- or green-emitting phosphors, for example.

The component A of the first phosphor can comprise Lu. In this case, Lu can be present in the first phosphor in a proportion of greater than or equal to 50 mol %, preferably greater than or equal to 90 mol %, particularly preferably 97.5 mol %.

Ga can be present in the first phosphor. The proportion of Ga can be 10 mol % to 40 mol %, preferably 15 mol % to 35 mol %, particularly preferably 25 mol %.

The first phosphor has the composition (Lu_{0.975}Ce_{0.025})₃(Al_{0.75}Ga_{0.25})₅O₁₂. Compared to conventional phosphors, the composition (Lu_{0.975}Ce_{0.025})₃(Al_{0.75} Ga_{0.25})₅O₁₂ exhibits particularly high absolute brightness values at the same temperature, a reduced temperature quenching behavior and thus an improved thermal stability.

During operation of the optoelectronic component, the primary electromagnetic radiation may be emitted by the layer sequence having an active region and impinges in a conversion region on the conversion material, which is arranged in the beam path of the primary electromagnetic radiation and is suitable for at least partly absorbing the primary electromagnetic radiation and emitting it as secondary electromagnetic radiation having a wavelength range that differs at least partly from that of the primary electromagnetic radiation.

Conversion region denotes that region in the optoelectronic component which comprises the conversion material and is arranged or applied, for example, as a layer, film, or as a potting material on or above the layer sequence having an active region. A layer comprising the conversion material can furthermore be composed of partial layers or partial regions, wherein conversion materials of different compositions are present in the individual partial layers or partial regions.

The fact that a region is arranged or applied “on” or “above” the layer sequence having an active region can in this case mean that the conversion region is arranged directly in direct mechanical and/or electrical contact on the layer sequence having an active region. Furthermore, it can also mean that the conversion region is arranged indirectly on or above the layer sequence having an active region. In this case, further layers, regions and/or elements can then be arranged between the conversion region and the layer sequence.

In this case, one or more first and second phosphors can be distributed or embedded in the conversion material of the conversion region homogenously or with concentration gradients in a matrix material. In particular, polymer or ceramic materials are suitable as matrix material. The matrix material can be selected from a group comprising siloxanes, epoxides, acrylates, methyl methacrylates, imides, carbonates, olefins, styrenes, urethanes, the derivatives and mixtures, copolymers or compounds thereof, wherein said compounds can be present in the form of monomers, oligomers or polymers. By way of example, the matrix material can comprise or be an epoxy resin, polymethyl methacrylate (PMMA), polystyrene, polycarbonate, polyacrylate, polyurethane or a silicone resin such as for instance, polysiloxane or mixtures thereof.

If the conversion region is shaped as a potting material, the conversion material can comprise at least one of potting compound, one or more first and second phosphors and one or more fillers. The potting material can be connected to the layer sequence having the active region for example firmly bonded by the potting compound. In this case, the potting compound can be polymer material, for example. In particular, this can be silicone, a methyl-substituted silicone, for example, poly(dimethylsiloxane) and/or polymethylphenylsiloxane, a cyclohexyl-substituted silicone, for example, poly(dicyclohexyl)siloxane, or a combination thereof.

Furthermore, the conversion material can additionally comprise a filler such as, for example, a metal oxide, thus for instance titanium dioxide, zirconium dioxide, zinc oxide, aluminium oxide, a salt such as barium sulphate and/or glass particles. The degree of filling of the filler in the conversion material, for example, can be greater than 20% by weight, for example, 25 to 30% by weight.

The mixing ratio of the first phosphor and of the second phosphor in the conversion material may be arbitrarily selectable.

The primary electromagnetic radiation and secondary electromagnetic radiation can comprise one or more wavelengths and/or wavelength ranges in an infrared to ultraviolet wavelength range, in particular in a visible wavelength range. In this case, the spectrum of the primary electromagnetic radiation and/or the spectrum of the secondary electromagnetic radiation can be narrowband, that is to say that the primary electromagnetic radiation and/or the secondary electromagnetic radiation can have a single-colored or approximately single-colored wavelength range. The spectrum of the primary electromagnetic radiation and/or the spectrum of the secondary electromagnetic radiation can alternatively also be broadband, that is to say that the primary electromagnetic radiation and/or the secondary electromagnetic radiation can have a mixed-colored wavelength range, wherein the mixed-colored wavelength range can in each case have a continuous spectrum or a plurality of discrete spectral components having different wavelengths.

By way of example, the primary electromagnetic radiation can have a wavelength range from an ultraviolet to green wavelength range, while the secondary electromagnetic radiation can have a wavelength range from a blue to infrared wavelength range. Particularly preferably, the primary electromagnetic radiation and the secondary electromagnetic radiation superimposed can give a white-colored luminous impression. For this purpose, the primary electromagnetic radiation can give a blue-colored luminous impression and the secondary electromagnetic radiation can give a yellow-colored luminous impression, which can arise as a result of spectral components of the secondary electromagnetic radiation in the yellow wavelength range and/or spectral components in the green and red wavelength range.

The primary electromagnetic radiation emitted by the layer sequence can have a wavelength of 300 to 485 nm, preferably 430 nm to 470 nm, particularly preferably 440 to 455 nm, in particular 442.5 nm to 452.5 nm.

The primary electromagnetic radiation may have a wavelength of 447.5 nm. The choice of the wavelength or wavelength range of the primary electromagnetic radiation of greater than 440 nm leads to an improved intrinsic thermal stability of the optoelectronic component. Through the choice of the wavelength or wavelength range of the primary electromagnetic radiation and of the conversion material, the color location of the total emission is influenced little even when there is a change in the temperature and/or the forward current I_{f} and a temperature- and current-stabilized behavior of the total emission is thus achieved. The color location stability of the total emission is significantly improved by the optimized interaction of the primary electromagnetic radiation with the sensitivity of the blue receptor in the human eye (CIE-Z, blue sensitively of the eye according to the CIE standard). Furthermore, the improved thermal stability significantly increases the efficiency of the component at higher temperatures. Furthermore, through the choice of a short-wave wavelength of the primary electromagnetic radiation, the wavelength dependence of the color rendering of the optoelectronic component is very low in comparison with conventional optoelectronic components.

In this case, the optoelectronic component may have a total emission composed of primary electromagnetic radiation and secondary electromagnetic radiation.

In particular, in this case the total emission can be perceived as white light by an external observer during the operation of the optoelectronic component.

The secondary electromagnetic radiation can be composed of a first secondary electromagnetic radiation emitted by the first phosphor, and a second secondary electromagnetic radiation emitted by the second phosphor. The first secondary electromagnetic radiation can have a wavelength of 490 nm to 575 nm, preferably 540 nm. The second secondary electromagnetic radiation can have a wavelength of 600 nm to 750 nm, preferably 630 nm. The first phosphor thus emits in the yellow or green spectral range of the electromagnetic radiation and the second phosphor in the orange or red spectral range of the electromagnetic radiation.

The conversion material can have an absorption spectrum and an emission spectrum, wherein the absorption spectrum and the emission spectrum are advantageously at least partly not congruent. Thus, the absorption spectrum can at least partly comprise the spectrum of the primary electromagnetic radiation and the emission spectrum can at least partly comprise the spectrum of the secondary electromagnetic radiation. Therefore, a secondary electromagnetic radiation is at least partly generated from primary electromagnetic radiation by the conversion material.

The conversion material may furthermore comprise at least one dye. Dyes can be, for example, organic dyes, inorganic dyes, fluorescent dyes. Exemplary dyes are perylene or coumarin.

In particular, to produce a conversion material shaped in a layered fashion, for example, the first and second phosphors can be applied in liquid form. If appropriate, the first and second phosphors can be mixed with a matrix material which can likewise be present in a liquid phase, and be applied jointly. If appropriate, the liquid matrix material and the first and second phosphors can be applied, for example, on the layer sequence having the active region. An electrode can also be applied on the layer sequence and first and second phosphors possibly mixed with a matrix material can be applied to the electrode in a layered fashion. By drying and/or crosslinking processes, the first and second phosphors or the mixture can be cured and/or fixed and the conversion material shaped in a layered fashion can be formed.

The second phosphor, for example, of the M₂Si₅N₈ type, wherein M is a combination of Ca, Sr, Ba and Eu, can be produced as follows: starting substances are weighed in stoichiometrically. If alkaline earth metal components are used for M, they can also be weighed in with an excess, in order possibly to compensate for evaporation losses during synthesis.

Starting substances can be selected from a group comprising alkaline earth metals and their compounds, silicon and its compounds, and europium and its compounds. In this case, alkaline earth metal compounds can be selected from alloys, hydrides, silicides, nitrides, halides, oxides and mixtures of these compounds. Silicon compounds can be selected from silicon nitrides, alkaline earth metal silicides, silicon diimides, silicon hydrides or mixtures of these compounds. Silicon nitrides and silicon metal are preferably used, these being stable, readily available and expedient. Compounds or europium can be selected from europium oxides, europium nitrides, europium halides, europium hydrides or mixtures of these compounds. Europium oxide is preferably used, this being stable, readily available and expedient.

It is also possible to use a flux to improve crystallinity and support crystal growth of the phosphor. In this case, it is possible to use the chlorides and fluorides of the alkaline earth metals used, such as SrCl₂, SrF₂, CaCl₂, CaF₂, BaCl₂, BaF₂, halides, such as NH₄Cl, NH₄F, KF, KCl, MgF₂, and boron-containing compounds, such as H₃BO₃, B₂O₃, Li₂B₄O₇, NaBO₂, Na₂B₄O₇.

Alternatively, a charge-neutral substitution of the SiN units in the second phosphor of the M₂Si₅N₈ type by AlO units is possible.

The starting substances are mixed, wherein mixing of the starting substances is preferably carried out in a ball mill or in a tumble mixer. During the mixing process, the conditions can be chosen such that enough energy is input into the material to be mixed, thus resulting in grinding of the starting substances. The resulting increased homogeneity and reactivity of the mixture can have a positive influence on the properties of the resulting phosphor.

By targeted variation of the bulk density and/or by modification of the agglomeration of the starting substance mixture, the production of secondary phases can be reduced. Moreover, the particle size distribution, particle morphology and the yield of the resulting second phosphor can be influenced. The techniques suitable for this are, for example, screening and granulation, if appropriate using suitable additives.

Afterwards, the mixture can be subjected to single or multiple heat treatment. The heat treatment can take place in a crucible composed of tungsten, molybdenum or boron nitride. The heat treatment takes place in a gas-tight furnace in a nitrogen or nitrogen/hydrogen atmosphere. The atmosphere can be flowing or stationary. It can additionally be advantageous for the quality of the second phosphor if carbon in finely divided form is present in the furnace chamber. Multiple heat treatments of the second phosphor can further improve the crystallinity or the grain size distribution. Further advantages can be a lower defect density in association with improved optical properties of the second phosphor and/or a higher stability of the second phosphor. Between the heat treatments, the second phosphor can be treated or it is possible to add to the second phosphor substances such as starting substances, fluxes, other substances or a mixture of these substances.

The heat-treated phosphor can furthermore be ground. Customary tools such as, for example, a mortar mill, a fluidized bed mill or a ball mill can be used for the grinding of the second phosphor. During grinding, the proportion of fragmented grain produced should in this case be kept as small as possible since the latter can impair the optical properties of the second phosphor.

Afterwards, the second phosphor can additionally be washed. For this purpose, the phosphor can be washed in water or in aqueous acids, such as hydrochloric acid, nitric acid, hydrofluoric acid, sulphuric acid, organic acids or a mixture thereof. As a result, secondary phases, vitreous phases or other impurities can be removed and an improvement in the optical properties of the second phosphor can thus be achieved. It is also possible, by this treatment, to dissolve out relatively small phosphor particles in a targeted manner and to optimize the particle size distribution for the application. Furthermore, it is possible to produce the second phosphor in particle form, in which case the surfaces of the particles can be altered by treatment in a targeted manner such as e.g. the removal of specific constituents from the particle surface. This treatment, possibly in conjunction with a downstream treatment, can lead to improved stability of the phosphor.

The first phosphor having the composition A₃B₅O₁₂ can be produced as follows. First, starting substances of the component A are provided, which are selected from a group comprising rare earth metal oxides, rare earth metal hydroxides and rare earth metal salts such as, for example, rare earth metal carbonates, rare earth metal nitrates, rare earth metal halides, and combinations thereof. As starting substances of the component B, it is possible to select oxides, hydroxides or salts of aluminium and gallium, such as, for example, their carbonates, nitrates, halides, or else combinations of the compounds mentioned.

In addition, it is possible to add to the starting substances fluxing agents or fluxes such as, for example, but not exclusively, fluorides such as, for example, NH₄HF₂, LiF, NaF, KF, RbF, CsF, BaF₂, AlF₃, CeF₃, YF₃, LuF₃, GdF₃, and similar compounds, or else boric acid, and the salts thereof. Furthermore, arbitrary combinations of two or more of the abovementioned fluxes are also appropriate.

The starting substances and, if appropriate, the fluxes and fluxing agents are homogenized, for example, in a mortar mill, a ball mill, a turbulent mixer, a plough share mixer or by means of other suitable methods. The homogenized mixture is subsequently annealed in a furnace, for example, a tubular furnace, a chamber furnace or a push-through furnace, for a number of hours under a reducing atmosphere for a number of hours. The annealed material is subsequently ground, for example, in a mortar mill, ball mill, fluidized bed mill or other types of mill. The ground powder is subsequently subjected to further fractionating and classifying steps such as, for example, screening, floatation or sedimentation, and if appropriate washed. The reaction product comprises the first phosphor.

Alternatively, the first and second phosphors and, if appropriate, a matrix material can also be vapor-deposited and then cured by crosslinking reactions. Furthermore, the particles of the first and/or second phosphor can at least partly scatter the primary electromagnetic radiation. The first and second phosphors can thus simultaneously be a luminous center that partly absorbs radiation of the primary electromagnetic radiation and emits a secondary electromagnetic radiation, and as a scattering center for the primary electromagnetic radiation. The scattering properties of the conversion material can lead to an improved coupling-out of radiation from the component. The scattering effect can, for example, also lead to an increase in the probability of absorption of primary radiation in the conversion material, as a result of which a small layer thickness of the layer containing the conversion material can be necessary.

Furthermore, the conversion material can also be applied on a substrate, which comprises glass or a transparent plastic, for example, wherein the layer sequence having the active region can be arranged on the conversion material.

The optoelectronic component can comprise an encapsulation enclosing the layer sequence having the active region, wherein the conversion material can be arranged in the beam path of the primary electromagnetic radiation within or outside the encapsulation. The encapsulation can in each case be a thin-film encapsulation.

Furthermore, a phosphor is specified which has the general composition A₃B₅O₁₂, wherein A is selected from a group comprising Y, Lu, Gd and Ce and combinations thereof, and wherein G comprises a combination of Al and Ga. The above explanations given with regard to the first phosphor of the optoelectronic component equally apply to this phosphor. Such a phosphor is suitable, in particular, as conversion material or constituent of a conversion material in optoelectronic components. If the phosphor is used in a conversion material in optoelectronic components, it can be present in the conversion material in a manner mixed with further phosphors, for example, a second phosphor such as has been described in connection with the optoelectronic component mentioned above, a matrix material, dyes and/or fillers.

Furthermore, a phosphor is specified which has the general composition M₂Si₅N₈, wherein M comprises a combination of Ca, Sr, Ba and Eu. The explanations given with regard to the second phosphor having the general composition M₂Si₅N₈ of the optoelectronic component equally apply to this phosphor. Such a phosphor is suitable, in particular, as conversion material or constituent of a conversion material in optoelectronic components. If the phosphor is used in a conversion material in optoelectronic components, it can be present in the conversion material in a manner mixed with further phosphors, for example, a first phosphor such as has been described in connection with the optoelectronic component mentioned above, a matrix material, dyes and/or fillers.

Further advantages and developments of our components and phosphors will become apparent from the examples described below in conjunction with the figures.

In the examples and the figures, identical or identically acting constituent parts are in each case provided with the same reference signs. The elements illustrated and their size relationships among one another should not be regarded as true to scale, in principle. Furthermore, identical examples of phosphors are provided with the same short designations.

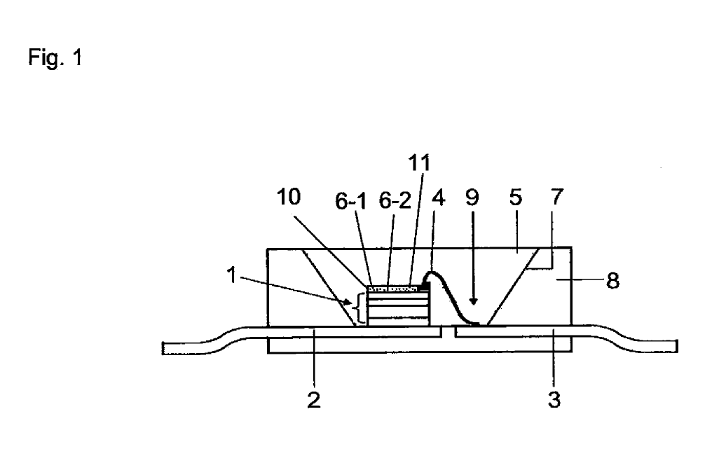

FIG. 1 shows a schematic side view of an optoelectronic component on the basis of the example of a light-emitting diode (LED). The optoelectronic component comprises a layer sequence 1 having an active region (not explicitly shown), a first electrical connection 2, a second electrical connection 3, a bonding wire 4, a potting material 5, a housing wall 7, a housing 8, a cutout 9, a conversion region 10 comprising a first phosphor 6-1, a second phosphor 6-2 and a matrix material 11.

Furthermore, the layer sequence having an active region can be arranged on a carrier (not shown here). A carrier can be, for example, a Printed Circuit Board (PCB), a ceramic substrate, a circuit board or an aluminium plate.

Alternatively, a carrierless arrangement of the layer sequence is possible in the case of so-called “thin-film chips.”

The active region emits primary electromagnetic radiation in an emission direction. The layer sequence having an active region can be based on nitride compound semiconductor material, for example. Nitride compound semiconductor material emits, in particular, primary electromagnetic radiation in the blue and/or ultraviolet spectral range.

There are arranged in the beam path of the primary electromagnetic radiation, in the conversion region 10, the first phosphor 6-1 and second phosphor 6-2, which as shown here are present in particle form and are embedded into a matrix material 11. The matrix material 11 is polymer or ceramic material, for example. In this case, the conversion region 10 is arranged directly in direct mechanical and/or electrical contact on the layer sequence 1 having an active region.

Alternatively, further layers and materials such as the potting material, for example, can be arranged between the conversion region 10 and the layer sequence 1 (not shown here).

Alternatively, the first phosphor 6-1 and second phosphor 6-2 can be arranged indirectly or directly at the housing wall 7 of a housing 8 (not shown here).

Alternatively, it is possible for the first phosphor 6-1 and second phosphor 6-2 to be embedded in a potting compound (not shown here), and for the conversion region 10 to be shaped as potting material 5.

First phosphor 6-1 and second phosphor 6-2 at least partly convert the primary electromagnetic radiation into a secondary electromagnetic radiation. By way of example, the primary electromagnetic radiation is emitted in the blue spectral range of the electromagnetic radiation, wherein at least part of the primary electromagnetic radiation is converted by the conversion material containing the first phosphor 6-1 and the second phosphor 6-2 to a first secondary electromagnetic radiation in the green and a second secondary electromagnetic radiation in the red spectral range of the electromagnetic radiation. The overall radiation emerging from the optoelectronic component is a superimposition of blue-emitting primary radiation and red- and green-emitting secondary radiation, wherein the total emission visible to the external observer is white light.

The following short designations are used for examples and comparative examples of phosphors:

L2: Example of a second phosphor having the composition (Sr_{0.36}Ba_{0.5}Ca_{0.1}Eu_{0.04})₂Si₅N₈
V2: Comparative example (Sr,Eu)₂Si₅N₈
V2-50% Ba: Comparative example (Sr_{0.46}Ba_{0.5}Eu_{0.04})₂Si₅N₈
V2-40% Ca: Comparative example (Sr_{0.56}Ca_{0.4}Eu_{0.04})₂Si₅N₈
V2-75% Ba: Comparative example (Sr_{0.21}Ba_{0.75}Eu_{0.04})₂Si₅N₈
V2-25% Ba: Comparative example (Sr_{0.71}Ba_{0.25}Eu_{0.04})₂Si₅N₈
V2-1: Comparative example (Ca,Eu)₂Si₅N₈
V2-2: Comparative example (Sr,Ba, Ca,Eu)₂SiO₄.

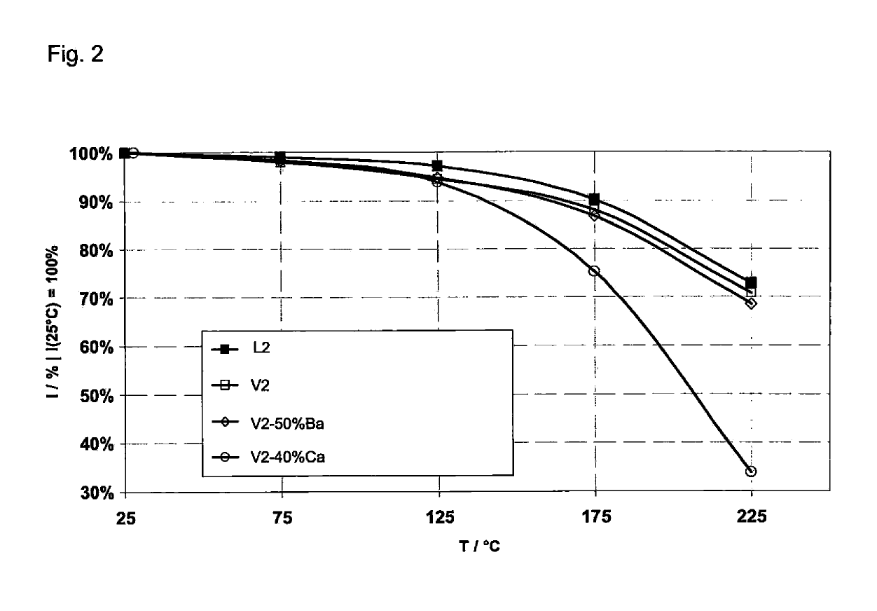

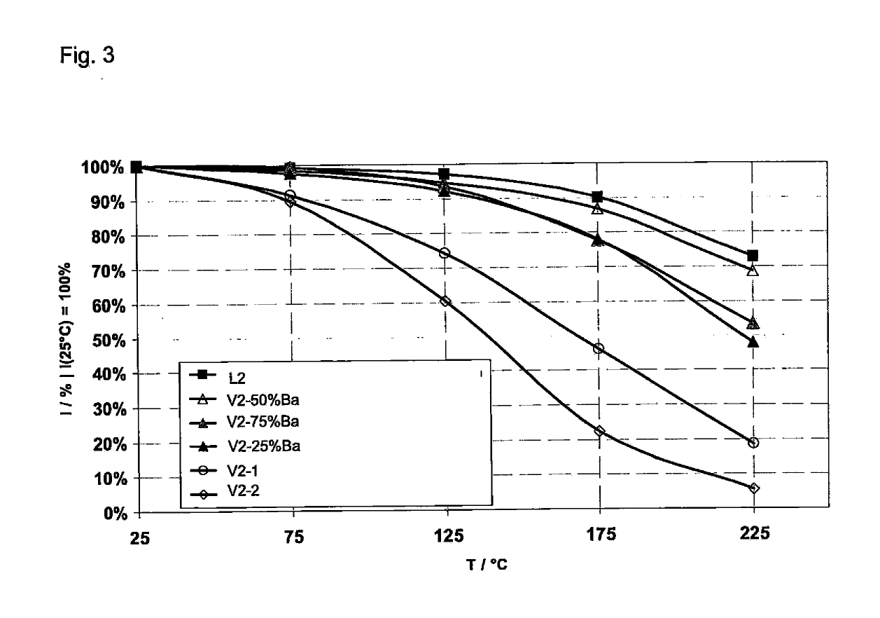

FIGS. 2 and 3 in each case show the relative brightness I in percent of the second phosphor L2 and of the comparative examples V2, V2-50% Ba, V2-40% Ca, V2-75% Ba, V2-25% Ba, V2-1 and V2-2 as a function of the temperature in ° C. The reference value, that is to say 100% brightness, was chosen at 25° C. These measurements characterize the temperature quenching behavior of the phosphors emitting in the orange or red spectral range of the electromagnetic radiation.

As can be seen in FIG. 2, the partial substitution of Sr by Ba proceeding from V2 leads to a greater decrease in the relative brightness values in V2-50% Ba and thus to an impaired thermal stability; the partial substitution of Sr by Ca proceeding from V2 in V2-40% Ca leads to a higher decrease in the relative brightness values and thus to a significantly poorer thermal stability.

The second phosphor L2 is surprisingly distinguished by a lower decrease in the brightness values as the temperature rises and thus a lower temperature quenching behavior and an improved thermal stability compared to the comparative examples V2, V2-50% Ba and V2-40% Ca. As the temperature rises, the relative brightness of the second phosphor L2 decreases to a lesser extent compared with the other comparative examples V2, V2-50% Ba and V2-40% Ca shown in FIG. 2.

As can be seen in FIG. 3, the second phosphor L2 is distinguished by higher relative brightness values I at the same temperature, a lower temperature quenching behavior and thus an improved thermal stability compared to the comparative examples of V2-50% Ba, V2-75% Ba, V2-25% Ba, V2-1 and V2-2. As the temperature rises, the relative brightness of the second phosphor L2 decreases to a lesser extent compared with the other comparative examples V2-50% Ba, V2-75% Ba, V2-25% Ba, V2-1 and V2-2 shown in the graph.

The following short designations are used for examples and comparative examples of phosphors:

L1-1: Example of a first phosphor having the composition (Lu_{0.975}Ce_{0.025})₃Al_{4.25}Ga_{0.75}O₁₂.
L1-2: Example of a first phosphor having the composition (Lu_{0.978}Ce_{0.022})₃Al_{3.75}Ga_{1.25}O₁₂.
V1-1: Comparative example Y₃(Al,Ga)₅O₁₂:Ce.
V1-2: Comparative example (Sr_{1-v-w}BaᵥEu_{w})₂SiO₄, wherein v≦1 and 0.01<w<0.2.
V1-3: Comparative example (Sr_{1-v-w}BaᵥEu_{w})₂SiO₄, wherein v≧1 and 0.01<w<0.2.

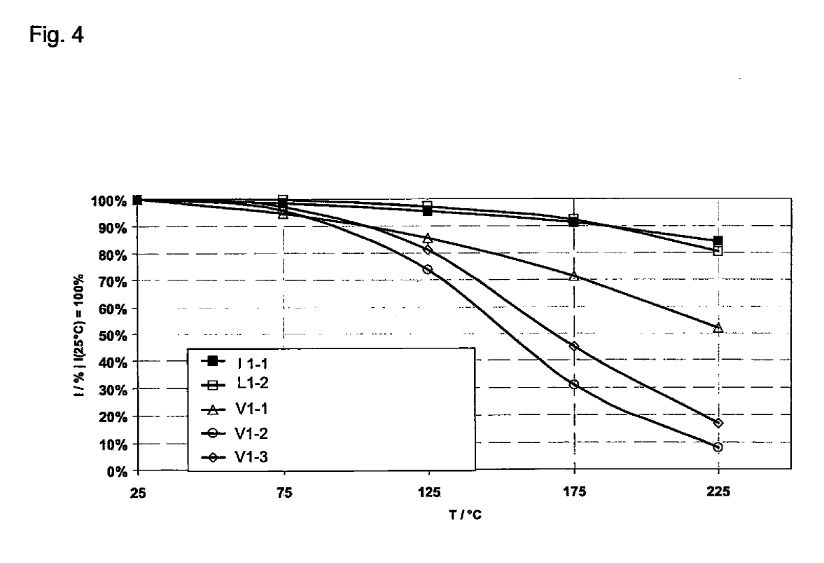

FIG. 4 shows the relative brightness I in percent of the first phosphors L1-1 and L1-2 emitting in the yellow or green spectral range of the electromagnetic radiation and of the comparative examples V1-1, V1-2 and V1-3 as a function of the temperature T in ° C. The reference value of the brightness I, that is to say 100%, was chosen at 25° C.

The first phosphors L1-1 and L1-2 are distinguished by higher relative brightness values at the same temperature, a lower temperature quenching behavior and thus an improved thermal stability compared to the comparative examples V1-1, V1-2 and V1-3. As the temperature rises, the relative brightness of the first phosphor L1-1 and L1-2 decreases to a lesser extent compared to the other comparative examples V1-1, V1-2 and V1-3 shown in the graph.

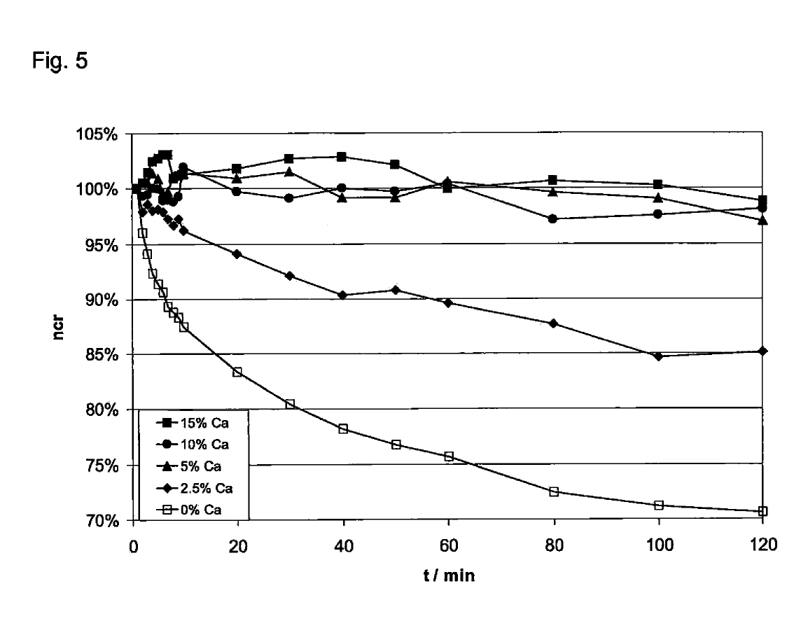

FIG. 5 shows the normalized conversion ratio or the conversion efficiency ncr as a function of time t in min as a result of a laser fast ageing test. This involved determining the stability of the orange- or red-emitting second phosphor (Sr,Ba, Ca,Eu)₂Si₅N₈ having a variable Ca content of 15 mol %, 10 mol %, 5 mol % and 2.5 mol % with a constant Ba content of 50 mol %. In this case, the proportion of Eu in the second phosphor (Sr,Ba, Ca,Eu)₂Si₅N₈ is 4 mol % to 5 mol %, wherein the sum of the proportions of Ca, Ba, Eu and Sr is 100%. The percentages indicated in FIG. 5 for the respective Ca proportion correspond to mole percent (mol %). FIG. 5 additionally shows the time dependence of the conversion efficiency ncr of the comparative example V2-50% Ba as a reference (0% Ca). For this purpose, the samples were exposed to an intensive laser radiation, wherein the laser radiation emits in the blue spectral range of the electromagnetic radiation, and the ratio of the integral of the emission spectrum of the laser radiation and the integral of the emission spectrum of the second phosphor (Sr,Ba, Ca,Eu)₂Si₅N₈ (conversion ratio) is determined in a temporally resolved manner. In FIG. 5, the measured values ncr relative to the start value at 1 min are in each case plotted for each composition. Higher values for the conversion ratio mean a higher phosphor stability. A significant stabilization can be observed as the Ca content rises in the second phosphor from 2.5% to 5%. From a Ca content of 5% on, the phosphors are highly stable within the scope of measurement errors.

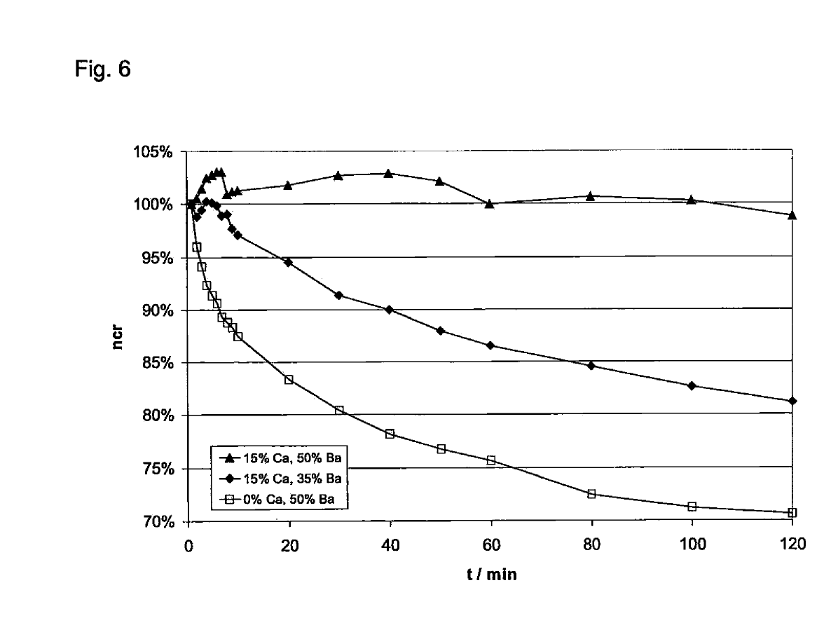

FIG. 6 shows, analogously to FIG. 5, the normalized conversion ratio or the conversion efficiency ncr as a function of time t in min. This involved determining the stability of the red- or orange-emitting second phosphor (Sr,Ba, Ca,Eu)₂Si₅N₈ having a variable Ba content of 50 mol % and 35 mol % (with a respective constant Ca content of 15 mol %). The comparative example V2-50% Ba is chosen as a reference. The percentages indicated in FIG. 6 for the respective Ca proportion or Ba proportion correspond to mole percent (mol %). With a constant Ca content of 15 mol % in the second phosphor (Sr,Ba, Ca,Eu)₂Si₅N₈, it is evident that a reduction in the Ba content below 50 mol % results in a great decrease in the ncr, and a destabilization of the second phosphor (Sr,Ba, Ca,Eu)₂Si₅N₈ is thus brought about. A Ba content of at least 50 mol % in the second phosphor of the M₂Si₅N₈ type exhibits high ncr values and thus exhibits long-term stability.

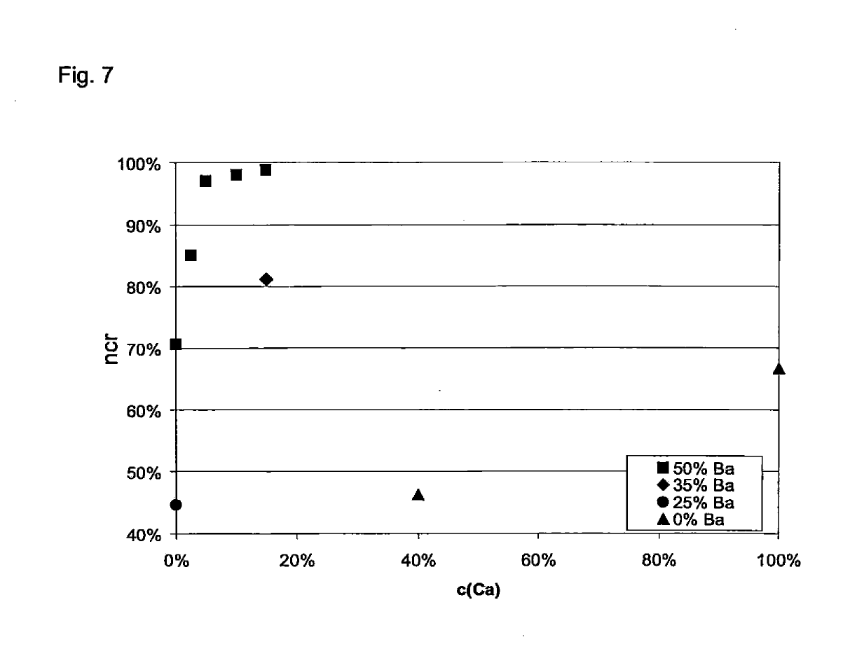

FIG. 7 shows the conversion ratio after 120 min, normalized to the value after 1 min. This involved determining the stability of the red- or orange-emitting second phosphor (Sr,Ba, Ca,Eu)₂Si₅N₈ having a Ba proportion of 50 mol %, 35 mol %, 25 mol % and of a comparative example V2-40% Ca (0% Ba) as a function of the Ca content c(Ca) in percent. The percentages indicated in FIG. 7 for the respective Ca proportion or Ba proportion correspond to mole percent (mol %). As the Ca content rises, the full width at half maximum of the emission rises, which is associated with a reduction in the visual useful effect. The phosphor chosen as optimal having approximately 50 mol % Ba and approximately 10 mol % Ca is highly stable within the scope of measurement errors and thus exhibits very good properties with regard to color rendering, stability, and efficiency.

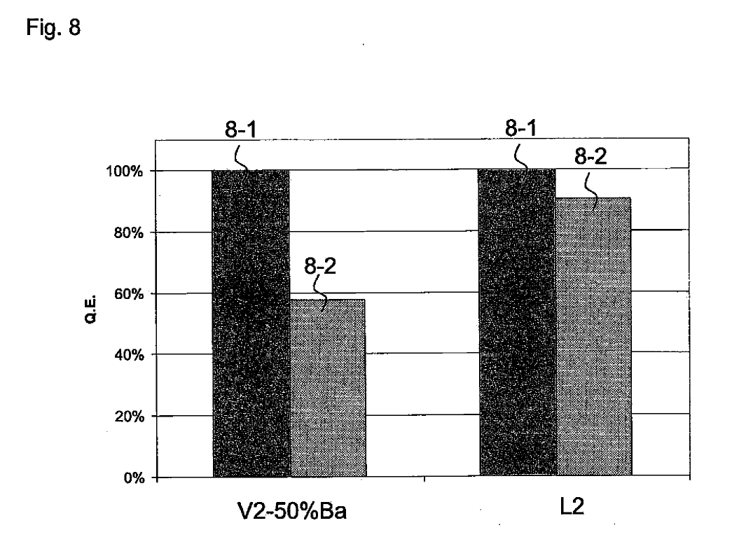

FIG. 8 shows the relative quantum efficiency Q.E. of the second phosphor L2 and of the comparative example V2-50% Ba as a result of an oxidation test. For this purpose, the respective samples were first characterized (8-1) in a first step by determining the Q.E., subsequently baked for 16 hours at 350° C. in air and subsequently characterized (8-2) again by determining the Q.E. Compared to the comparative example V2-50% Ba, the second phosphor L2 is distinguished by the fact that it exhibits a significantly smaller decrease in the Q.E. after baking (8-2) and thus has a higher stability. Consequently, the proportion of Ca in L2 in comparison with the comparative example V2-50% Ba exhibits a stabilizing influence on the system.

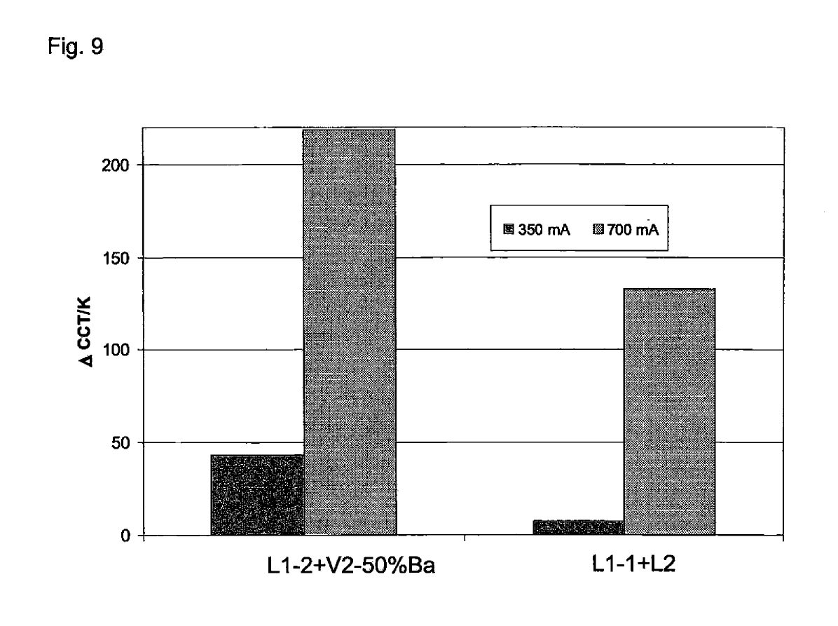

The following designations are used in the following FIGS. 9 to 14:

L1-1+L2: Mixture of an example of the first phosphor having the composition (Lu_{0.975}Ce_{0.025})₃Al_{4.25}Ga_{0.75}O₁₂ and of an exemplary embodiment of the second phosphor having the composition (Sr_{0.36}Ba_{0.5}Ca_{0.1}Eu_{0.04})₂Si₅N₈, wherein the mixing ratio is 4 to 1.

L1-2+V2-50% Ba: comparative example of a mixture of an example of the first phosphor having the composition (Lu_{0.978}Ce_{0.022})₃Al_{3.75}Ga_{1.25}O₁₂ and of the comparative example (Sr_{0.46}Ba_{0.5}Eu_{0.04})₂Si₅N₈, wherein the mixing ratio is 7 to 1.

FIG. 9 shows the difference in the correlated color temperature ACCT/K between the measured value after 300 s continuous operation and the measured value at the start of the measurement of L1-1+L2 and of L1-2+V2-50% Ba for two different current intensities of 350 mA and 700 mA. A significant reduction of the color temperature drift of L1-1+L2 and thus a higher stability of the color location in comparison with the comparative example L1-2+V2-50% Ba are observed.

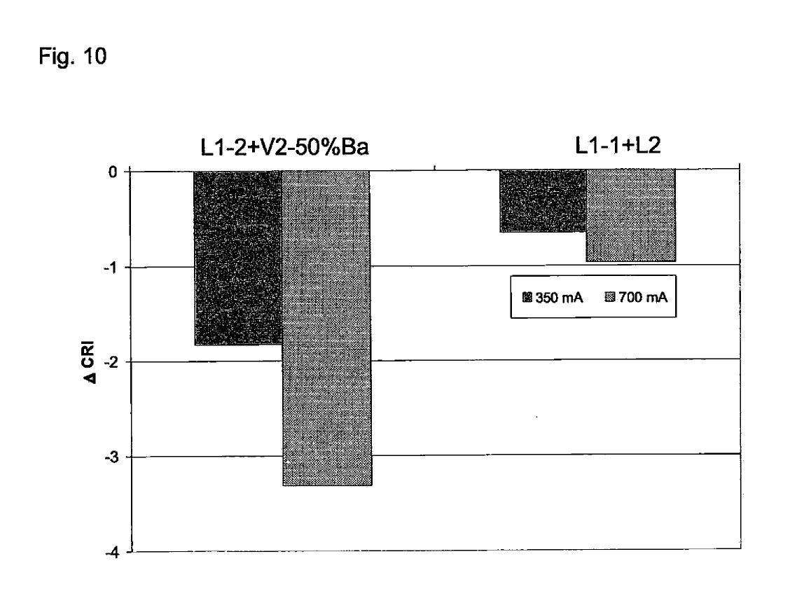

FIG. 10 shows the difference in the color rendering index ACRI (corresponding to ΔRa), during continuous operation of a light-emitting diode (LED) at two different current intensities of 350 mA and 700 mA of L1-1+L2 and of L1-2+V2-50% Ba. The figure shows in each case the difference in the color rendering index ACRI between the measured value after 300 s continuous operation and the measured value at the start of the measurement. A significant reduction of the CRI loss for L1-1+L2 and thus a higher stability of the color rendering index CRI compared to the comparative example L1-2+V2-50% Ba are observed.

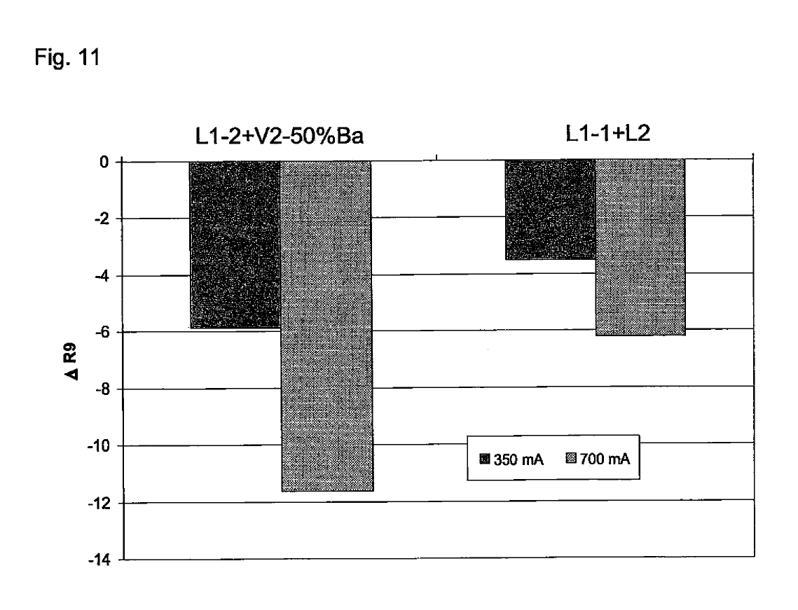

FIG. 11 shows the difference in the color rendering index ΔR9 (saturated red) during continuous operation of a light-emitting diode (LED) at two different current intensities of the 350 mA and 700 mA of L1-1+L2 and of L1-2+V2-50% Ba. The difference in the color rendering index ΔR9 between the measured value after 300 s continuous operation and the measured value at the start of the measurement is in each case plotted in the graph. A significant reduction of the R9 loss of L1-1+L2 and thus a significant stability of the color rendering index R9 in comparison with the comparative example L1-2+V2-50% Ba is observed.

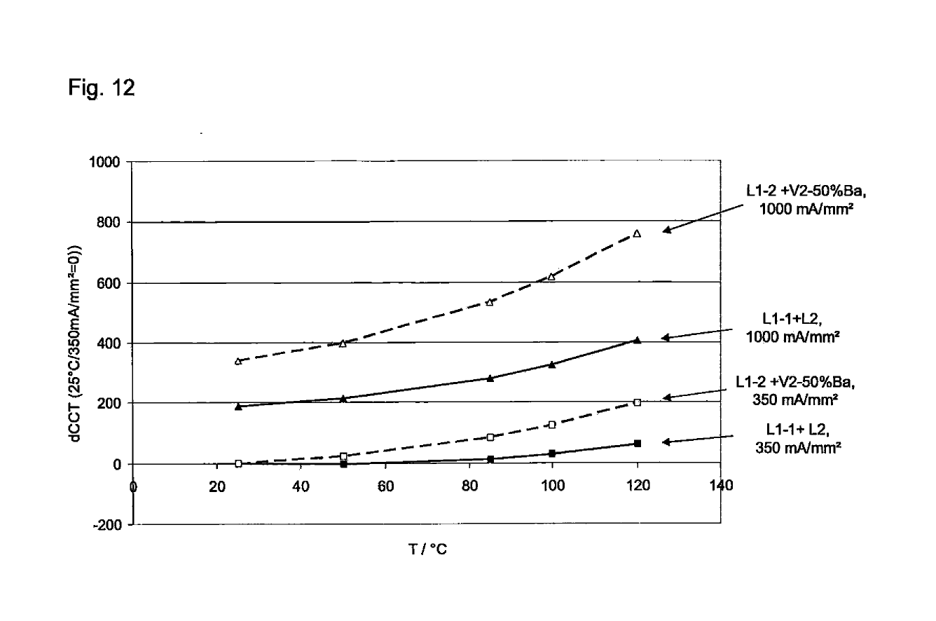

FIG. 12 shows the change in the color temperature dCCT as a function of the temperature T in ° C. of a light-emitting diode (LED) of L1-1+L2 and of the comparative example L1-2+V2-50% Ba in each case at a current density of 350 mA/mm² and 1000 mA/mm². The experiment was carried out with a 20 ms pulsed measurement at a wavelength of the primary electromagnetic radiation of 447 nm for L1-1+L2 and at 440 nm for the comparative example L1-2+V2-50% Ba. L1-1+L2 has a significantly smaller change in the color temperature in comparison with the comparative example L1-2+V2-50% Ba. As the temperature rises, the change in the color temperature of L1-1+L2 increases to a lesser extent compared to the color temperature of the comparative example L1-2+V2-50% Ba. The increase in the current density exhibits a smaller change in the color temperature dCCT of L1-1+L2 compared to the comparative example L1-2+V2-50% Ba. Therefore, a significant stabilization of the color temperature over the temperature or the operating current is manifested for L1-1+L2.

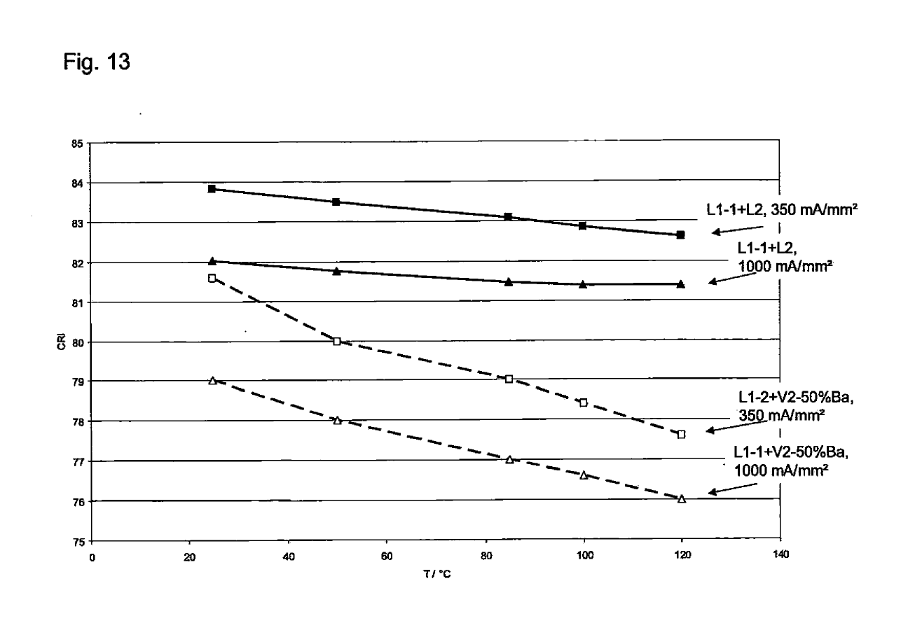

FIG. 13 shows the color rendering index CRI as a function of the temperature T in ° C. of a light-emitting diode (LED) of L1-1+L2 and of the comparative example L1-2+V2-50% Ba at different current densities of 350 mA/mm² and 1000 mA/mm². L1-1+L2 exhibits for comparable current density a lesser decrease in the CRI values as the temperature rises, and a smaller decrease in the CRI values when the current density is increased, and thus a significant stabilization of CRI over the temperature or the operating current compared to the comparative example L1-2+V2-50% Ba.

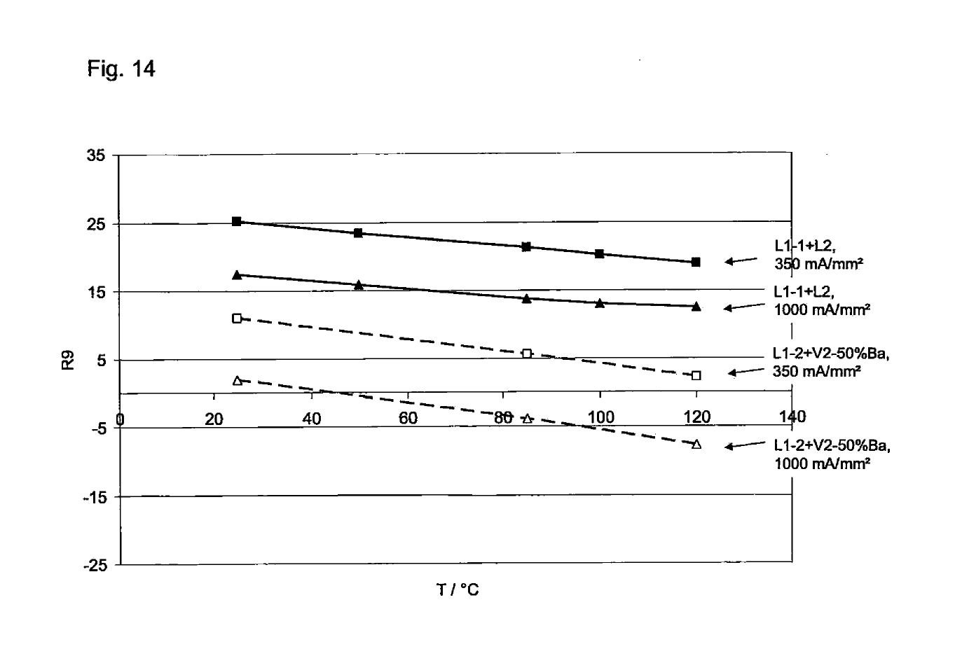

FIG. 14 shows the color rendering index R9 as a function of the temperature T in ° C. of a light-emitting diode (LED) of L1-1+L2 and of the comparative example L1-2+V2-50% Ba at different current densities of 350 mA/mm² and 1000 mA/mm². L1-1+L2 exhibits for comparable current density a lesser decrease in the R9 value as the temperature rises, and a smaller decrease in the R9 values when the current density is increased, and thus a significant stabilization of R9 over the temperature or the operating current compared to the comparative example L1-2+V2-50% Ba.

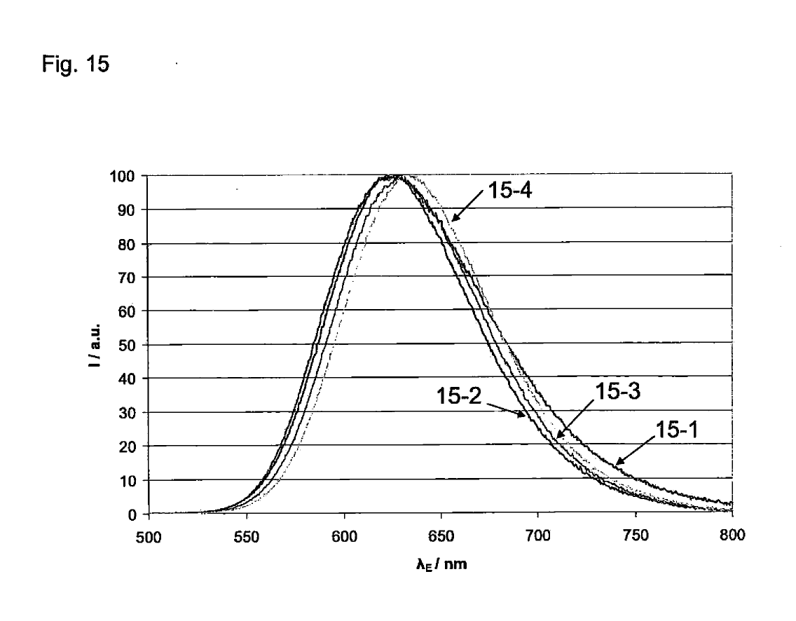

FIG. 15 shows a comparison of the emission spectra of the second phosphor L2 (curve 15-1) with a second phosphor of the (Sr_{1-a-b}CaₐEu_{b})AlSiN₃ type, wherein a is 0.4 (curve 15-2), 0.5 (curve 15-3) or 0.6 (curve 15-4) and b is 0.003 in each case. The relative intensity I in a.u. as a function of the emission wavelength λ_{E} in nm is shown. In this case, the second phosphor L2 (curve 15-1) and the second phosphor of the (Sr_{1-a-b}CaₐEu_{b})AlSiN₃ type (curves 15-2 to 15-4) exhibit comparable emission spectra and emission wavelength maxima. Consequently, the second phosphor of the (Sr_{1-a-b}CaₐEu_{b})AlSiN₃ type (curves 15-2 to 15-4) is an alternative second phosphor L2.

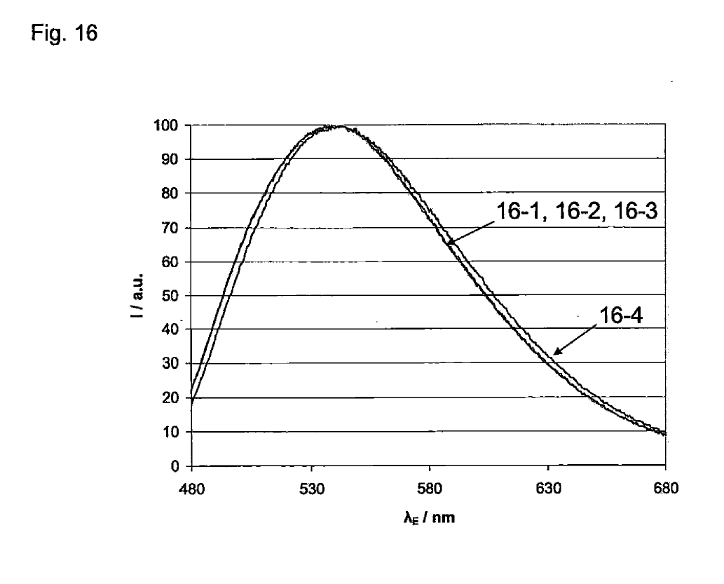

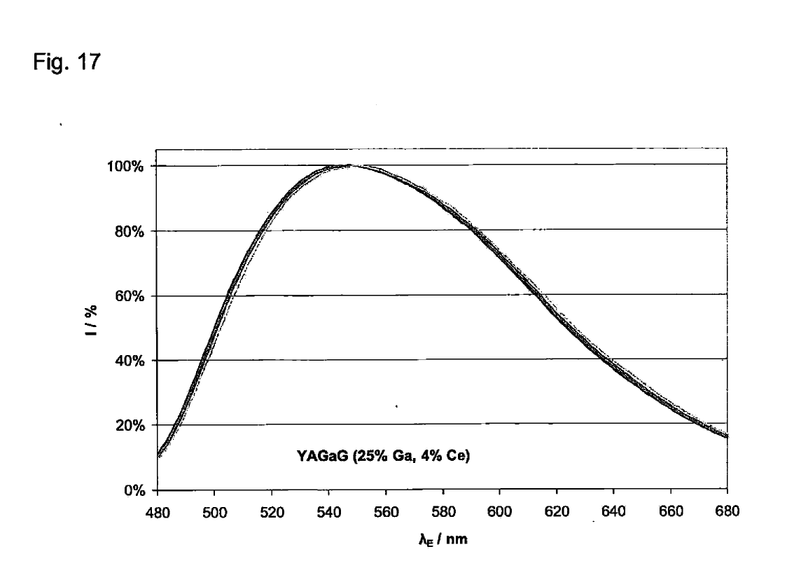

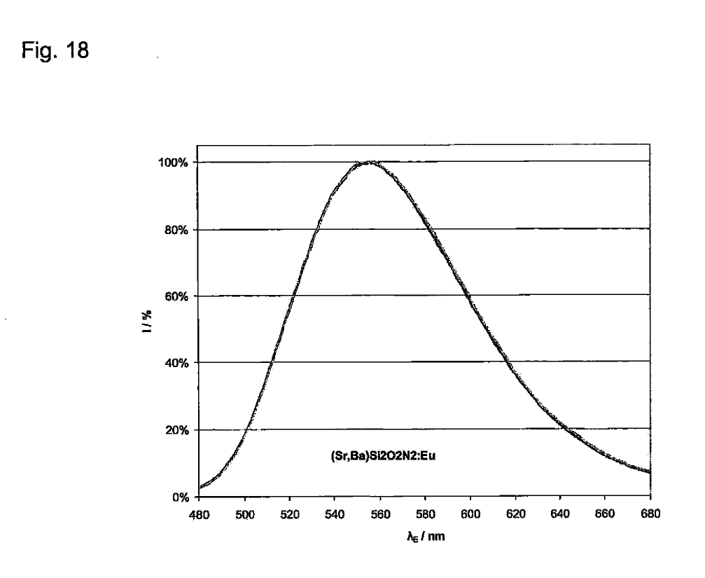

FIG. 16 shows the normalized intensity I in a.u. as a function of the emission wavelength λ_{E} in nm of the first phosphor L1-1 at a variable excitation wavelength of 435 nm (curve 16-1), 440 nm (curve 16-2), 445 nm (curve 16-3) and 460 nm (curve 16-4). In comparison therewith, comparative examples of the YAGaG type (25% Ga, 4% Ce) (FIG. 17) and of the (Sr,Ba)Si₂O₂N₂:Eu type (FIG. 18) are shown.

FIGS. 17 and 18 show the relative intensity I in percent as a function of the emission wavelength λ_{E} in nm of a comparative example of the YAGaG type (25% Ga, 4% Ce) (FIG. 17) and (Sr,Ba)Si₂O₂N₂:Eu type (FIG. 18). The percentages indicated in FIG. 17 for the Ga and Ce proportions in each case correspond to mole percent (mol %). 430 nm, 440 nm, 450 nm, 460 nm and 470 nm were chosen as excitation wavelength. The curves in FIGS. 17 and 18 practically all lie above one another and, for the sake of clarity, the individual curves are not identified separately.

Surprisingly, the first phosphor L1-1 exhibits a significant shift in the absorption wavelength to smaller values into the green spectral range of the electromagnetic radiation with decreasing excitation wavelength to 430 to 470 nm (FIG. 16, curves 16-1 to 16-4) compared to the comparative examples YAGaG (25% Ga, 4% Ce) in FIG. 17 and (Sr,Ba)Si₂O₂N₂:Eu in FIG. 18.

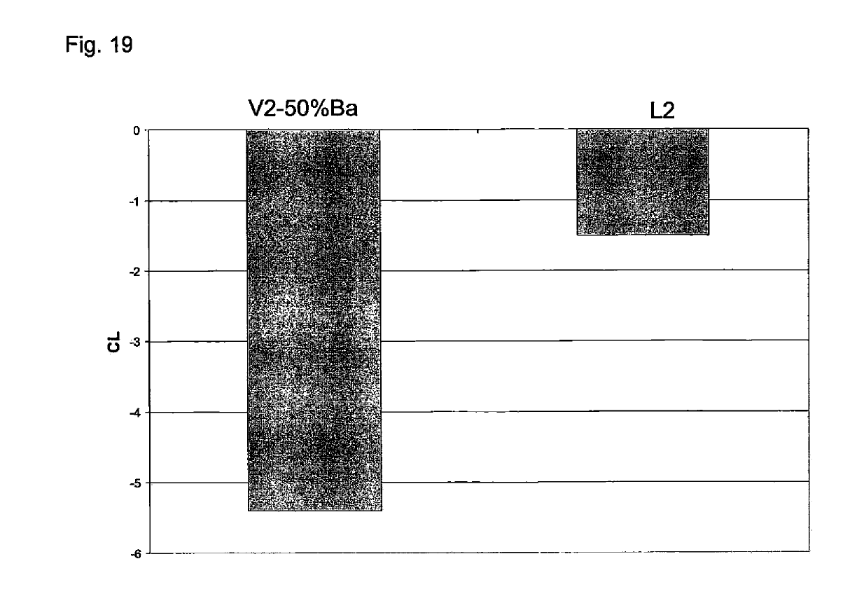

FIG. 19 shows the converter loss CL of the second phosphor L2 and of the comparative example V2-50% Ba. This involved testing the phosphors L2 and V2-50% Ba in each case in a light-emitting diode for 1000 hours at an operating temperature of 85° C. and a current intensity of 500MA. The second phosphor L2 exhibits a lower converter loss and thus lesser ageing in comparison with the comparative example V2-50% Ba.

The production of a second phosphor (example 1) and of a first phosphor (example 2) are in each case described below on the basis of examples.

### Example 1

27.891 g Sr₃N₂, 56.280 g BaN_{0.94}, 3.554 g Ca₃N₂, 40.398 g silicon metal powder, 16.815 g silicon nitride and 5.062 g europium oxide are weighed in and intensively mixed in a 500 ml PET container with 20 beads composed of zirconium oxide for 6 hours on a roller bed. The starting substance mixture is screened by a 400 μm screen gauze and filled in a crucible composed of molybdenum with cover. Annealing takes place for 4 hours at 1580° C. in a tubular furnace in a flowing atmosphere (92.5% N₂/7.5% H₂; 2 l/min). Afterwards, the second phosphor is ground in a mortar mill for a few minutes and screened by a 31 μm screen gauze. The screened material is annealed one more time in a molybdenum crucible in a flowing atmosphere (92.5% N₂/7.5% H₂; 2 l/min) for 4 hours at 1580° C. in a tubular furnace. Afterwards, the second phosphor is ground in a mortar mill for a few minutes and screened by a 31 μm screen gauze. The screened material is dispersed in one liter of water, 200 ml of 2 molar hydrochloric acid are added thereto and intensive stirring is carried out. After 10 minutes, the aqueous phase is decanted off. The residual sediment is filled with distilled water to 4 liters and the phosphor is dispersed by intensive stirring. After 20 minutes, the supernatant water is decanted off from the sediment. This process is repeated again twice. The dried sediment comprises the second phosphor having the composition (Sr_{0.36}Ba_{0.5}Ca_{0.1}Eu_{0.04})₂Si₅N₈.

### Example 2

64.39 g of lutetium oxide Lu₂O₃, 0.99 g of cerium oxide CeO₂, 21.15 g of aluminium oxide Al₂O₃, 12.96 g of gallium oxide Ga₂O₃ and 0.50 g of cerium fluoride CeF₃ are mixed and ground together for two hours in a 250 ml polyethylene wide-necked flask with 150 g of aluminium oxide beads having a diameter of 10 mm. The mixture is annealed in a covered corundum crucible for three hours at 1550° C. in forming gas (nitrogen comprising 5% by volume hydrogen). The annealed material is ground in an automatic mortar mill and screened by a screen having a mesh width of 31 μm. The resulting phosphor has a strong green-yellow body color. The reaction product comprises a first phosphor having the composition ((Lu_{0.975}Ce_{0.025})₃(Al_{0.75}Ga_{0.25})₅O₁₂).

Our components, phosphors and methods are not restricted by the description on the basis of the examples. Rather, this disclosure encompasses any novel feature and also any combination of features, which in particular includes any combination of features in the appended claims, even if the feature or the combination itself is not explicitly specified in the claims or examples.

1.-18. (canceled)

19. An optoelectronic component comprising:
a layer sequence having an active region that emits primary electromagnetic radiation, wherein the primary electromagnetic radiation has a wavelength of 430 nm to 470 nm,
a conversion material arranged in a beam path of the primary electromagnetic radiation and at least partly converts the primary electromagnetic radiation into a secondary electromagnetic radiation, wherein the conversion material comprises a first phosphor having general composition A₃B₅O₁₂, wherein A is a combination of Lu and Ce, Lu can be present in the first phosphor in a proportion of greater than or equal to 90 mol %, and wherein B is a combination of Al and Ga, a proportion of Ga can be 10 mol % to 40 mol %, and the conversion material comprises a second phosphor, and the second phosphor is selected from a group of the following second phosphors and combinations thereof:
second phosphor from an M⁴-Al—Si—N system comprising a cation M⁴, wherein M⁴ comprises Ca or a combination of Ca with at least one further element from the group consisting of Ba, Sr, Mg, Zn and Cd, wherein the second phosphor is activated with Eu that partly replaces M⁴, wherein the second phosphor forms a phase that can be assigned to a system M⁴₃N₂—AlN—Si₃N₄, wherein an atomic ratio of constituents M⁴:Al≧0.375 and an atomic ratio Si/Al≧1.4,
second phosphor from an M⁵-Al—Si—N system comprising a cation M⁵, wherein M⁵ comprises Ca or Ba or Sr, wherein M⁵ can additionally be combined with at least one further element selected from the group consisting of Mg, Zn and Cd, the second phosphor is activated with Eu that partly replaces M⁵, the second phosphor additionally contains LiF, and a proportion of LiF is at least 1 mol %, relative to M⁵,
second phosphor M¹AlSiN₃.Si₂N₂O,
second phosphor M³AlSiN₃, and
second phosphor M₂Si₅N₈, wherein M is a combination of Ca, Sr, Ba and Eu, M¹ is selected from the group consisting of Sr, Ca, Mg, Li, Eu and combinations thereof, and M³ is selected from the group consisting of Sr, Ca, Mg, Li, Eu and combinations thereof.

20. The optoelectronic component according to claim 19, wherein the second phosphor is M¹AlSiN₃.Si₂N₂O and/or M³AlSiN₃ and/or M₂Si₅N₈.

21. The optoelectronic component according to claim 19, wherein the second phosphor is M₂Si₅N₈ and Ca is present in the second phosphor in a proportion of 2.5 mol % to 25 mol %.

22. The optoelectronic component according to claim 19, wherein the second phosphor is M₂Si₅N₈ and Ba is present in the second phosphor in a proportion that is greater than or equal to 40 mol %.

23. The optoelectronic component according to claim 19, wherein the second phosphor is M₂Si₅N₈ and Eu is present in the second phosphor in a proportion of 0.5 mol % to 10 mol %.

24. The optoelectronic component according to claim 19, wherein the second phosphor is (Sr_{0.36}Ba_{0.5}Ca_{0.1}Eu_{0.04})₂Si₅N₈.

25. The optoelectronic component according to claim 19, wherein M⁵ of the second phosphor from the M⁵-Al—Si—N system is Ca alone or predominantly, to the extent of more than 50 mol %, and/or the proportion of LiF in the second phosphor from the M⁵-Al—Si—N system is at least 1 mol % and a maximum of 15 mol %, relative to M⁵.

26. The optoelectronic component according to claim 19, wherein the second phosphor from the M⁴-Al—Si—N system has a stoichiometry M⁴_{5-δ}Al_{4-2δ+y}Si_{8+2δ-y}N_{18-y}O_{y}:Eu where |δ|≦0.5 and 0≦y≦2.

27. The optoelectronic component according to claim 19, wherein the primary electromagnetic radiation has a wavelength of 440 nm to 455 nm.

28. The optoelectronic component according to claim 19, wherein the secondary electromagnetic radiation is composed of a first secondary electromagnetic radiation emitted by the first phosphor, and a second secondary electromagnetic radiation emitted by the second phosphor.

29. The optoelectronic component according to claim 19, wherein the first secondary electromagnetic radiation has a wavelength of 490 nm to 575 nm.

30. The optoelectronic component according to claim 19, wherein the second secondary electromagnetic radiation has a wavelength of 600 nm to 750 nm.

31. The optoelectronic component according to claim 19, wherein A comprises Ce and is present in the first phosphor in a proportion of 0.5 mol % to 5 mol %.

32. The optoelectronic component according to claim 19, wherein the first phosphor is (Lu_{0.975}Ce_{0.025})₃(Al_{0.75}Ga_{0.25})₅O₁₂).

33. The optoelectronic component according to claim 19, which has a total emission composed of primary electromagnetic radiation and secondary electromagnetic radiation.

34. A phosphor having a general composition A₃B₅O₁₂, wherein A is selected from the group consisting of Y, Lu, Gd, Ce and combinations thereof, and wherein B comprises a combination of Al and Ga.

35. A phosphor having a general composition M₂Si₅N₈, wherein M comprises a combination of Ca, Sr, Ba and Eu.
